(19) United States
(12) Patent Application Publication
(10) Pub. No.: US 2009/0301867 A1
(43) Pub. Date: Dec. 10, 2009

(54) INTEGRATED SYSTEM FOR SEMICONDUCTOR SUBSTRATE PROCESSING USING LIQUID PHASE METAL DEPOSITION

(75) Inventors: Janos Farkas, Saint Ismier (FR); Cindy Goldberg, Austin, TX (US); Katie Yu, Austin, TX (US); Srdjan Kordic, Eindhoven (NL)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: CITIBANK N.A., NEW YORK, NY (US)

(21) Appl. No.: 12/280,482

(22) PCT Filed: Feb. 24, 2006
(86) PCT No.: PCT/EP06/02853

§ 371 Date: Dec. 18, 2008

(51) Int. Cl. C25B 9/00; B05C 5/00; B05C 11/00; C23C 16/00

(52) U.S. Cl. 204/242; 118/300; 118/72; 118/729

(57) ABSTRACT

A system for processing a semiconductor substrate during fabrication of semiconductor devices provides a plurality of semiconductor substrate processing stations in a physically integrated system, as well as a semiconductor substrate transport system for transporting a semiconductor substrate between the respective processing stations. In particular, the processing system according to the present invention favors the use of liquid phase process steps, particularly deposition process steps, instead of gas or vapor phase processing. Even more particularly, the system contemplates deposition of a metallic barrier layer 30 on the semiconductor substrate in liquid phase.

### FIELD OF THE INVENTION

The present invention relates to an integrated system for processing semiconductor substrates during the fabrication of semiconductor devices. In a particular example, the system includes an integrated plurality of processing stations for performing respective process steps in semiconductor device fabrication, at least including a sidewall barrier layer deposition station for depositing a sidewall barrier layer on the semiconductor substrate in liquid phase.

### BACKGROUND OF THE INVENTION

As the size of features of integrated circuits decreases, it is increasingly important to reduce the resistance-capacitance delay (RC delay) attributable to interconnects used in such circuits. One approach is to use interconnects having a reduced dielectric constant (k), which can be obtained, for example, by using appropriate low-k materials. In one example, carbonated silicon dioxide (SiOC) films are conventionally known in 90-120 nm technology nodes. A further known approach is to further reduce the dielectric constant by using porous carbonated silicon dioxide films.

The term “carbonated silicon dioxide films” and the corresponding formula “SiOC” are used to designate silicon dioxide films including carbon therein (e.g., by using CH₃SiH₃ in place of the SiH₄ that is often used as a precursor in CVD deposition of a silicon dioxide layer). Such films are sometimes also referred to in the art as carbon-doped silicon dioxide films.

Carbonated silicon dioxide films are being developed by several vendors, using chemical vapor deposition or spin-on coating techniques. Several vendors are currently developing CVD-deposited SiOC films using a “porogen” approach. With this technology, the porogens are built into a dielectric film and are degassed during the post-treatment, leaving pores in the film. Applied Materials (Black Diamond IIx; III), Novellus systems (ELK Coral), Trikon (Orion), and ASM are amongst the companies working on this approach. Suppliers of spin-on porous dielectric materials include Dow Chemicals (SiLK), Rohm & Haas (Zirkon), and JSR.

However, it is known in the art that a silicon oxide-containing material (like a carbonated silicon dioxide) has a substantial population of surface hydroxyl (also referred to herein as silanol) groups on its surface. These groups have a strong tendency to take up water because they are highly polarized. They are generated by the break up of four and six member bulk siloxane (Si—O—Si) bridges at the surface of the material. These siloxane structures at the material surface have an uncompensated electric potential and so can be considered to be “strained”. They react readily with ambient moisture to form the surface hydroxyl groups. If the silicon oxide-containing material is porous, the surface hydroxyls and the adsorbed water molecules tend to propagate into the bulk of the material, undesirably increasing the dielectric constant and reducing film reliability.

A comparable effect occurs in other materials, such as metal oxides, present on the surface of a wafer. The metal ion-oxide bonds located at the surface of the material have an uncompensated electric potential. This likewise leads to a ready reaction with ambient moisture so as to form surface hydroxyl groups. Once again, if the material is porous, the surface hydroxyls and adsorbed water molecules will propagate to the bulk of the material and lead to an unwanted increase in dielectric constant.

As mentioned above, carbonated silicon oxide is often used as a porous dielectric material. Its carbon-rich surface has relatively fewer strained oxide bonds. Thus, there is a reduced population of surface hydroxyls at the surface of the material.

However, the tendency for water uptake is still quite high in carbon-containing porous dielectric materials after a dry etch process. The oxidizing plasma reduces the carbon content at the surface of the material and therefore increases the population of surface hydroxyls. The dielectric constant k therefore increases after dry etching, so the k value of the film must be “restored.” An example of such a restoration of the dielectric constant is the application of a supercritical CO₂ treatment with hexamethyldisilazane (HMDS).

In addition to problems caused by moisture present in ambient air, it is also conventional to use aqueous cleaning solutions to clean the surface of the wafer during semiconductor fabrication.

For example, when a semiconductor integrated circuit is manufactured, vias and other trench-like structures must be etched in one or more layers formed on a semiconductor substrate. When vias or trench-like structures are etched, polymer residues may build up because of a reaction between hydrocarbon etchant gases in the plasma and the substrate material. In addition, metallic species (e.g. copper) may be inadvertently sputtered onto the sidewalls.

It is thus desirable to clean a surface of the wafer to remove the polymer residues (and metallic species, if any), before proceeding to the subsequent stages in the manufacturing process. Conventional cleaning processes may use aqueous cleaning solutions such as dilute hydrofluoric acid (HF) or organic acid/base solutions.

However, these types of aqueous cleaning solutions may not be suitable when the surface being cleaned has a tendency to adsorb water, and particularly when the surface is porous, such as the surface of a porous dielectric layer. If aqueous cleaning solutions are to clean a wafer having a porous dielectric layer thereon, the porous material may adsorb water from the cleaning fluids. This problem can be even more problematic if the porous dielectric layer is damaged by plasma etching during the etching process.

Besides negatively affecting the dielectric constant of the porous dielectric layer, adsorbed water can also cause problems during subsequent stages in the manufacture of the circuit, notably degassing and reliability problems.

For the reasons described above, it is important to prevent water adsorption and uptake if porous dielectric materials are used to form interconnects. Moreover, moisture uptake in a porous dielectric could possibly corrode metallic barrier layers subsequently formed thereon.

Some known approaches to combat moisture uptake by porous dielectric materials during manufacture and use of a semiconductor integrated circuit include “dielectric restoration” as referred to hereinabove, as well as “pore sealing.”

Pore sealing involves prevention of access to the pores in the porous material, for example, by modifying the surface of the porous material (e.g. using an organosilane treatment). Alternatively, a thin dielectric film may be deposited on the surface of the porous dielectric layer. More particularly, the thin dielectric film can be applied to the porous dielectric layer after vias have been etched therein.

In addition to the foregoing issues concerning porous dielectric materials, subsequent conventional metallization (i.e., the formation of various metal layer structures, including barrier layers) is relatively slow and complex, and is therefore relatively expensive. In this regard, atomic layer deposition, chemical vapor deposition, and physical vapor deposition are typical methods for forming metal layers. Such processes require, in particular, separate and relatively complex process equipment operating under strict operating conditions. This also undesirably increases the overall footprint of equipment necessary for fabrication. Also, the effectiveness of metal layer deposition depends on the nature of the underlying surface. In some cases, metallization can be significantly retarded by an unfavorable underlying surface.

In addition, conventional gas and/or vapor phase process equipment is usually application specific. That is, a CVD reaction chamber, for example, can generally only be used for CVD processing. This means that a semiconductor device fabrication line requires a relatively large number of difference pieces of separate process equipment. An issue related to using separate pieces of equipment is that transporting semiconductor substrates between them is a delicate process that may expose substrates to external contamination and the like. For example, this may cause adhesion problems between layers of the structure.

U.S. Pat. No. 6,110,011, U.S. Pat. No. 6,143,126, U.S. Pat. No. 6,294,059, and U.S. Pat. No. 6,352,467 disclose general examples of integrated semiconductor substrate processing systems, but none are believed to emphasize the above-noted drawbacks of gas/vapor phase processing or useful alternatives thereto, especially with respect to metal deposition.

Patent Application No. PCT/EP2005/001510 (filed Feb. 15, 2005) describes a technique for cleaning via and trench structures after an etching step, using liquid cleaning agents. Patent Application No. PCT/EP2005/010688 (filed Sep. 1, 2005) describes a polymeric composition for passivating a porous, low dielectric constant dielectric layer while simultaneously providing reaction sites promoting the electroless metal layer deposition thereon.

### SUMMARY OF THE INVENTION

Accordingly, the present invention relates to an integrated system for processing semiconductor substrates during the manufacture of semiconductor devices thereon as described in the claims appended hereto.

### BRIEF DESCRIPTION OF THE DRAWINGS

The presently described and claimed invention will be even more clearly understandable with respect to the drawings appended hereto, in which:

FIG. 1 illustrates a sequence of fabrication steps, given by way of example, performed in an integrated apparatus according to an embodiment of the present invention, given strictly by way of example; and

FIG. 2 is a fragmentary cross-sectional view of a portion of a semiconductor device structure fabricated in accordance with an embodiment of the present invention.

### DETAILED DESCRIPTION OF PREFERRED EMBODIMENTS

Some preferred embodiments of the present invention are described hereinbelow.

The mention of a “semiconductor substrate” herein includes and encompasses, without limitation, semiconductor wafers, partially cut groups of semiconductor dice, and individual semiconductor chips. The mention of structures or layers or the like formed “on” a semiconductor substrate may include the presence of the structure or layer or the like directly or indirectly on the surface of the semiconductor substrate.

As mentioned above, the present invention relates to an integrated system for processing semiconductor substrates in the course of manufacturing semiconductor devices. In general, the system includes a plurality of processing stations and a transport mechanism for moving a semiconductor substrate between the processing stations. The processing stations use liquid phase deposition instead of gas or vapor phase deposition to the extent possible in order to permit faster, simpler, and less expensive processing.

The plurality of processing stations includes at least a metal barrier layer deposition station for depositing a liquid phase metallic barrier layer. The system may also include a coupling layer deposition station for depositing a coupling layer having a chemical composition that functions to promote and otherwise facilitate the subsequent formation of the metallic barrier layer. An example of such a coupling layer composition is described in Patent Application No. PCT/EP2005/010688.

Other processing stations for performing conventional semiconductor processing steps can be included in the system in any appropriate or otherwise desired combination. Examples of other processing stations that could be provided in the integrated system of the present invention include, without limitation, a substrate front and backside cleaning station, an electroplating station, a seed layer deposition station, a polishing station (such as a chemical mechanical polishing station or an electropolishing station), and a curing station (for example, a thermal curing station) having a controlled atmosphere. These stations use conventionally known approaches in order to provide their respective functionalities.

A transport system is provided in order to transport semiconductor substrates from one station to another in the integrated system. According to one aspect of the present invention, the transport system is automatically controlled in a known manner, such as by appropriate control software running on a computer. The transport system may, for example, be constructed and arranged to transport semiconductor substrates wholly within the structure of the integrated system, so as to increase protection against contamination and the like.

The transport system may be of any conventional type known in the art. These include systems of trays and the like for holding a respective semiconductor substrate thereon, cassettes for holding more than one semiconductor substrate, or automatically controlled grabbers, pincers, or the like. Each substrate holding unit for retaining a substrate (that is, each tray, cassette, grabber, etc.) may be moved throughout the processing system from station to station in a known manner, such as by selectively attaching each unit to circulating cables, chains, conveyors or the like. The movement of each substrate holding unit is also preferably automatically controlled.

Transport systems structured along linear paths of travel may be particularly suitable for serial processing of a semiconductor substrate in which a sequence of processing stations are used in a unidirectional order, without backtracking.

In contrast, it may be useful to provide a centrally located transport system with respect to a cluster of processing stations, such as a robotic arm provided with, for example, a known gripper type end located so as to be essentially surrounded by the plurality of processing stations. This arrangement is useful if one or more processing stations (such as a thermal treatment station) are used more than once during fabrication. In addition, this arrangement can present a desirably reduced footprint. Known examples of this general physical arrangement are illustrated in U.S. Pat. No. 6,352,467 and U.S. Pat. No. 6,294,059.

Contamination of semiconductor substrates during manufacture is a well-recognized problem in the art of semiconductor manufacturing art. Accordingly, it should be understood that conventional measures to avoid contamination are preferably a part of the system as contemplated, such as defining a closed environment in which substrates are transmitted from one station to another. The integration of the various processing stations in a single unit naturally facilitates such protected transport of substrates.

Other known environmental controls may be applied as needed or desired, for example and without limitation, providing an overpressure within the integrated system to resist an intake of contaminants, using technically appropriate construction materials to avoid chemical reactions with structures on the substrates, etc.

Cassettes holding a plurality of semiconductor substrates can be used to increase the throughput of processing, instead of moving substrates through the integrated system one at a time. An example of such a cassette is described, for example, in U.S. Pat. No. 6,352,467.

In an example of semiconductor fabrication according to the present invention, the use of porous dielectric materials is known, particularly for their desirably low dielectric constants. Accordingly, it is contemplated to provide a processing station for depositing such porous dielectric layers. As mentioned above, spin-on deposition and CVD-based porogen processes are some examples of processes known in the art for depositing porous dielectric layers.

However, it is known in the art that a silicon oxide-containing material (like a carbonated silicon dioxide) tends to have a substantial population of surface hydroxyl (silanol) groups on its surface. Because these surface hydroxyl groups are highly polarized, they react readily with ambient moisture. If the silicon oxide-containing material is porous, the surface hydroxyls and the adsorbed water molecules tend to propagate into the bulk of the material, causing, for reasons known in the art, an increase in the dielectric constant and reducing film reliability.

Therefore, a contemplated solution is to cover or passivate the porous dielectric material in order to prevent such moisture uptake, but without undesirably increasing the dielectric constant k of the material being passivated.

In general, according to the present invention, a processing station can be provided so that a passivation material is applied to the porous dielectric layer surface so as to react with the surface hydroxyls which are present thereon, as discussed hereinabove. The processing station can use standard means for applying the passivation material, such as in liquid form through nozzles and the like, or a vapor deposition process. In a particular example, spray application in a controlled neutral atmosphere (such as argon) is contemplated.

This reaction between the passivating coupling material and the surface hydroxyl groups in effect causes one or more steric shielding functional groups present in the passivating material molecules to be attached on the surface of the porous dielectric. The gaps between the attached shielding groups are too small to allow water molecules to reach the surface of the porous dielectric material. The attached shielding groups thus provide steric shielding to block or at least hinder the passage of moisture into the underlying porous material.

The shielding groups of the passivating coupling material may be considered optional in some circumstances, especially if the layer being passivated is less prone, or even not prone, to adsorb and/or take up moisture, such as in the case of non-porous dielectric layers.

The molecules of the passivating coupling material preferably also provide metal nucleation sites that facilitate and promote the formation of a metal layer, compared with metal deposition without the presence of the passivating layer. For this reason, reference may be made to a passivating coupling layer or, if passivation is not necessary, simply a coupling layer.

A variety of materials can be used to passivate the porous dielectric material according to the present invention. In general, an appropriate passivating coupling material according to the present invention:
includes at least one functional group that can react with surface hydroxyls commonly present on the surface of the porous dielectric material,
includes a second functional group (i.e., a ligand) having an electron donor functionality to provide a reactive site (more specifically, a metal nucleation site) on the passivated surface for subsequent metallization,
preferably, but not necessarily, includes at least two silicon atoms in the molecular backbone for thermally stabilizing the passivating coupling material, especially during subsequent relatively high temperature processing steps, and
preferably, but not necessarily, includes a plurality of organic shielding groups, which form at least one, and preferably at least two, steric shielding layers above the surface of the porous dielectric layer for blocking moisture uptake.

It is also advantageous if the passivating coupling material is soluble and the functional group(s) thereof has/have a relatively fast reaction speed with respect to surface hydroxyls, as explained below.

The passivating coupling material could for example be usefully soluble in water. However, it may also be useful to have a material soluble in alcohols (such as, for example, ethanol or isopropanol) or in a non-aqueous organic solvent like toluene.

The passivating coupling material may include at least one functional group which can be hydrolyzed in water.

An example of a passivating coupling material is an organosilane according to the following general formula:

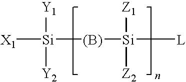

in which:

n is an integer equal to or greater than 1 (i.e., 1, 2, 3, 4, 5, 6, 7 . . . ),

each Si is a silicon atom;

X₁ is a functional group able to react with a respective surface hydroxyl site on a porous dielectric material.

Y₁ is either:
—X₂, which is a further functional group able to react with a surface hydroxyl site of the porous dielectric material,
—H, which is a hydrogen atom, or
—R₁, which is an organic apolar group;

Y₂ is either:
—X₃, which is a further functional group able to react with a surface hydroxyl site of the porous dielectric material,
—H, which is a hydrogen atom, or
—R₂, which is an organic apolar group

B, the presence of which is optional, is a bridging group,

Z₁ is either:
—R₃, which is an organic apolar group,
—H, which is a hydrogen atom, or
-L₁, which is a ligand having an electron donor functionality and is able to act as a metal nucleation site,

Z₂ is either:
—R₄, which is an organic apolar group,
—H, which is a hydrogen atom, or
-L₂, which is a ligand having an electron donor functionality and is able to act as a metal nucleation site, and

L is a ligand having an electron donor functionality and is able to act as a metal nucleation site.

The strength of the bond between the passivating coupling material and the porous dielectric material, and the speed at which it reacts with the surface hydroxyls is believed to depend on what specific functional groups are present in the passivating coupling material and on the number of the silicon groups in the passivating coupling material.

Organosilanes form stronger bonds to the surface compared with hydrocarbon chains that do not contain silicon, and therefore provide more stable protection for the porous dielectric layer surface. Also, the optional presence of at least one, and preferably at least two, silicon atoms in the main chain (“backbone”) of the molecule as described herein increases the thermal stability of the composition, particularly in view of the temperatures encountered in performing subsequent process steps. For example, after liquid phase metallization, a subsequent dielectric layer deposition and cure may entail temperatures of, for example, about 350° C. At such temperatures, a polymeric molecule having carbon (for example, aliphatic or aromatic carbon) in the backbone would likely oxidize.

In the foregoing molecule, at least one of the organic apolar groups R₁, R₂, R₃, and R₄ is present to provide steric shielding from the hydroxyl groups and water molecules by presenting at least one, and preferably at least two, steric shielding layers according to their connection to the respective Si atoms in the composition.

Studies in other fields suggest that properly chosen organic layers could be efficient to sterically shield non-porous dielectric surfaces from precursors (such as metalorganic compounds), see, for example, J. Farkas et al., J. Electrochem. Soc. 141, 3547 (1994). With porous materials it could be expected that the size of the shielding groups R should be proportional to the size of pores.

The effect of R on steric shielding by organosilanes has been studied in the field of high-pressure liquid gas chromatography column treatment. See, for example, K. Szabo et al, Helv. Chimi. Acta. vol. 67, p. 2128, (1984).

The Farkas et al. paper showed that an organic layer less than about 25 Angstroms thick can be efficient for sterically shielding a surface from water penetration, even at elevated temperatures. When using a passivation material to shield a porous dielectric surface, the length of the hydrocarbon chain can be easily adjusted to optimize the efficiency of steric shielding to the pore size of the dielectric.

According to an embodiment of the invention, the organic apolar group(s) R₁, R₂, R₃, and/or R₄ may be an optionally halogenated C₁ to C₁₀ alkyl, C₂ to C₁₀ alkenyl, or C₆ to C₁₀ aryl or aralkyl group, which is/are preferably selected from: methyl, ethyl, propyl, butyl, phenyl, pentafluorophenyl, 1,1,2-trimethylpropyl(thexyl), and allyl.

That is, R₁ and/or R₂, if present as Y₁ and/or Y₂, will form a first steric shielding layer; R₃ and/or R₄, if present as Z₁ and/or Z₂, forms a second, third, fourth, fifth, etc., steric shielding layer depending on the number n of monomers present in the chain.

Functional groups X₁, X₂, and X₃ should have a structure such that they are able to react with the surface hydroxyl sites of the porous dielectric material and attach one of more shielding layers in the passivating coupling material to the surface of the porous dielectric material. More particularly, these functional groups react by eliminating surface hydroxyls.

Some examples of appropriate functional groups in this regard include, without limitation, -chloride, -bromide, iodine, acryloxy-, alkoxy-, acetamido, acetyl-, allyl-, amino-, cyano-, epoxy-, imidazolyl, mercapto-, methanosulfonato-, sulfonato-, triflouroacetamido, and urea-containing groups

The ligands should have an electron donor functionality. Once the molecule is attached to the surface of the porous dielectric material, they forms reaction sites for metal nucleation during a subsequent liquid phase metallization process.

Ligands appropriate to the present invention include, without limitation, vinyl, allyl, 2-butynyl, cyano, cyclooctadienyl, cyclopentadienyl, phosphinyl, alkylphosphinyl, sulfonato, and amine groups.

In certain instances, the functional groups for reacting with the surface hydroxyl groups on the dielectric layer and the ligands could be the same mono-, bi-, and tri-functional amines (which would form strong interactions with both the porous dielectric thereunder and the metal layers subsequently formed thereon).

The contemplated passivating coupling composition will be illustrated by way of several representative and non-limitative examples. It will be appreciated that the example polymeric molecules shown below can be made longer or shorter according to the number of n monomers that are present therein. The index n is most generally an integer of 1 or greater. More preferably, n is an integer between 1 and 30, inclusive. Most preferably, n is an integer between 1 and 18, inclusive, i.e., 1, 2, 3, 4, 5, 6 . . . 17, or 18.

The bridging group B, if present, can be, for example, a divalent bridging group (such as oxygen or sulfur), a trivalent bridging group (such as nitrogen or phosphorus), or a tetravalent bridging group (such as carbon or silicon), and may be, more particularly, silylene and unsaturated aromatic carbon-containing groups such as m-phenylene, p-phenylene, and p,p′-diphenyl ether. The bridging group, when present, may further improve the thermal stability of the passivating coupling material molecule.

### Example 1

### Methoxy-tetramethyl-vinyl-disilane

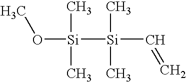

in which the X₁ functional group is H₃CO— (methoxy)group; the Y₁, Y₂, Z₁, Z₂ functional groups are —CH₃ (methyl)organic shielding groups; B is absent; and the ligand L is a —CH═CH₂ vinyl group.

### Example 2

### Trimethoxy-dimethyl-vinyl-disilane

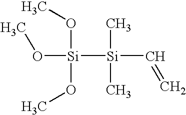

in which the X₁, Y₁, and Y₂ functional groups are H₃CO— (methoxy groups); the Z₁ and Z₂ functional groups are CH₃ methyl organic shielding groups; B is absent; and the ligand L is a —CH═CH₂ vinyl group.

### Example 3

### Vinyltetramethylmethoxydisiloxane (Bridging group B Present)

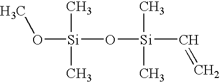

in which the X₁ functional group is a H₃CO— (methoxy) group; the Y₁, Y₂, Z₁, Z₂ functional groups are —CH₃ (methyl) organic shielding groups; the bridging group B is oxygen (forming a disiloxane compound); and the ligand L is a C═CH₂ vinyl group.

The addition of a bridging group B (such as oxygen in this example) can significantly affect the thermal stability of the coupling layer. Silylene and unsaturated carbon-containing carbene groups such as m-phenylene, p-phenylene, and p,p′-diphenyl ether are additional examples of bridging groups that can be used according to this invention to further improve the thermal stability of the passivating coupling material molecule.

### Example 4

### Methoxy-tetramethyl-butyl-disilane (Alternative Ligand)

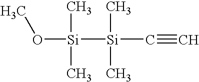

in which the X₁ functional group is a H₃CO— (methoxy) group; the Y₁, Y₂, Z₁, Z₂ functional groups are —CH₃ (methyl) organic shielding groups; the bridging group B is absent; and the ligand L is a —C≡CH acetylenyl group.

### Example 5

### Methoxy-hexamethyl-vinyl-trisilane (Alternative Molecule Length)

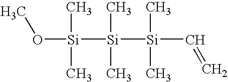

in which the X₁ functional group is a H₃CO— (methoxy) group; Y₁, Y₂, Z₁, Z₂ functional groups are —CH₃ (methyl) organic shielding groups; the bridging group B is absent; and the ligand L is a —CH═CH₂ (vinyl) group.

In general, the passivating coupling material can be applied on the surface of a porous dielectric material in accordance with known methods for applying an organic molecule or compound, including, generally and without limitation, gas phase, liquid phase, or spray chamber application. The physical equipment necessary for each type of application is considered well-known in the art.

However, liquid phase application, if used, must address the above-noted issues of moisture adsorption, as the passivating coupling material is typically diluted in water, possibly with an organic solvent (such as, for example, alcohol) added to further increase the solubility of the polymer. Also, some of the noted examples of functional groups suitable for the present invention can be hydrolyzed. Liquid phase application can be performed, for example, at temperatures between about 25° C. and 80° C. with process times between about 30 s to 10 min.

With respect to the possibility of liquid phase deposition of the passivating coupling material, the present invention most generally contemplates the use of an aqueous solution containing the passivating coupling material to deposit a passivating coupling layer over a dielectric layer. Preferably, the reaction speed between the passivating coupling material and silanols (i.e., surface hydroxyls) formed on the surface of the porous dielectric layer is sufficiently fast such that that reaction takes places before any appreciable uptake of moisture from the aqueous solvent occurs.

In other words, the reaction between the passivating coupling composition and the surface hydroxyls should be fast enough to substantially shield the porous dielectric layer from moisture before the dielectric layer starts to adsorb water from the solvent.

In a particular situation, it is known that polymeric residues may form on the semiconductor wafer, particularly (but not necessarily only) because of chemical reactions between hydrocarbon etching gases and the substrate material during a preceding etching step. As a result, the application of the passivating coupling material can be impeded by the presence of regions covered by such residues.

Thus, the passivating coupling material can be combined with an aqueous cleaning composition appropriate for removing the polymeric residues. As mentioned above, the reaction speed should be sufficiently fast so that, in this situation, the passivating coupling material reacts with surface hydroxyl groups on the surface of the porous dielectric material essentially as soon as the residues are removed by the cleaning composition. Water adsorption can therefore be blocked.

It will be appreciated that in this case a cleaning process step and a coupling layer deposition step can be carried out at the same processing station in the system of the present invention. Otherwise, a different physical cleaning station could be provided in the system to apply the appropriate cleaning solutions.

For example, if the passivating coupling material is a water-soluble organosilane, it can be mixed with the cleaning fluid(s) ahead of application thereof to the wafer. However, if the passivating coupling material consists of an organosilane which is traditionally considered not to be water-soluble when mixed with water, it can be still be used in certain embodiments of the present invention. More particularly, if the organosilane has a short pot life when mixed with water, the organosilane and the cleaning fluid(s) can mixed at, or in the immediate vicinity of, the cleaning tool (i.e. just before application to the wafer).

According to one example, therefore, a passivating process using the passivating coupling material of the present invention includes the following parameters:
the applied cleaning mixture is a soluble organosilane (according to the description herein) mixed with an organic acid, or highly diluted aqueous HF, or a salt thereof, and optionally includes a chelating agent and/or surfactant
process temperature=25-80° C., and
process time=30 s to 10 min

After the residual polymers and/or metallic residues are removed, the porous dielectric material is sealed by the passivating coupling layer.

As indicated above, additional complexing or chelating agents may be used if needed to remove metallic species. Such reagents should be added into the solution, so as to be able to be processed in a common series of steps. Common complexing agents that can be used in this manner include, without limitation, ethylenediaminetetraacetic acid (EDTA) and its derivatives, and organic acids.

Similarly, a wide variety of surfactants can be included in the solution if desired. For example, it may be advantageous to use block co-polymers built from blocks of poly(ethyleneoxide) and poly(propyleneoxide) as a surfactant. These two groups are efficiently absorbing on both hydrophobic and hydrophilic surfaces, and the length and ratio of each group present in the block co-polymer can easily be tailored to a given application.

Yet another possible approach is to deposit the passivating coupling material in multiple (i.e., at least two) process steps by depositing two or more organic components that, together, constitute the final passivating coupling material composition. The use of multiple components in this manner can, in particular, increase the range of silanes that could be used.

For example, in a first process step of a multi-step process, the porous dielectric surface is reacted with a first silane component. At least one of the functional groups presented by the first silane component reacts with the surface hydroxyls on the porous dielectric surface. In doing so, the first silane component seals the porosity of the underlying layer while leaving at least one hydrolizable functional group on the surface. Preferably, the reaction is carried out in a controlled atmosphere like nitrogen or argon to increase the range of usable silanes. In the absence of moisture and oxygen, an aggressive sylilating agent (e.g., triflourosulfonates, aminosilanes, etc.) can be applied.

After dehydrating the surface and sealing the porosity thereof, an aqueous via-cleaning step can be performed. In this step, at least one functional group at the other “end” of the first silane polymeric component is hydrolyzed so as to present one or more silanol groups. These silanol groups are the sites at which respective functional groups of a second silane component react so as to couple electron donor ligands to the silanol groups. As was explained with respect to the passivating coupling composition generally, the ligands are nucleating sites for subsequent liquid phase metal barrier deposition.

An appropriate first polymeric component for the first step is, for example, an organosilane according to the following general formula:

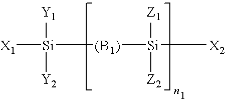

in which:
n₁ is an integer greater than or equal to 1,
each Si is a silicon atom;
X₁ is a functional group able to react with a surface hydroxyl site of the dielectric material,
Y₁ is either:
   —X₃, which is a further functional group able to react with a surface hydroxyl site of the dielectric material,
   —H, which is a hydrogen atom, or
   —R₁, which is an organic apolar group;
Y₂ is either:
   —X₄, which is a further functional group able to react with a surface hydroxyl site of the dielectric material,
   —H, which is a hydrogen atom, or
   —R₂, which is an organic apolar group,
B₁, the presence of which is optional, is a bridging group,
Z₁ is either:
   —R₃, which is an organic apolar group,
   —H, which is a hydrogen atom, or
   —X₅, which is a hydrolizable functional group, and
Z₂ is either:
   —R₄, which is an organic apolar group,
   —H, which is a hydrogen atom, or
   —X₆, which is a hydrolizable functional group; and
X₂ is a hydrolizable functional group.

Some examples of first organosilane components according to the description include:

### Example 1

### (Strong Amino (Basic) Group for Dehydrating, and Weak Methoxy Group for Rehydrating Methanol Bi-Product (Inert to Surface))

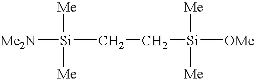

### Example 2

### Increase the Efficiency of Steric Shielding by Additional Organic Groups

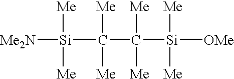

### Example 3

### Silicon Backbone to Increase Thermal Stability

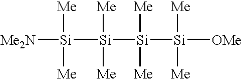

### Example 4

### Aromatic Bridging Group to Increase Thermal Stability

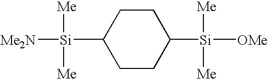

### Example 5

### Strong Hydrolyzable Amino Groups on both Ends—Amine (Basic) Product; Aromatic Bridging Group

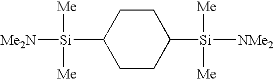

### Example 6

### Strong Fluoromethenesulfonate Hydrolyzable Groups on both Ends—Trifluorometanesulfanete (Acid) Product

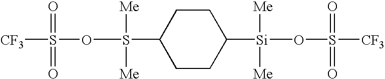

An appropriate polymeric component for the second step is an organosilane according to the general formula:

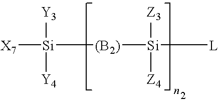

in which:
n₂ is an integer equal to or greater than or equal to 0, each Si is a silicon atom;
X₇ is a functional group able to react with a hydrolyzed functional group of the first organosilane molecule,
Y₃ is either:
   —X₈, which is a further functional group able to react with a hydrolyzed functional group of the first organosilane molecule,
   —H, which is a hydrogen atom, or
   —R₅, which is an organic apolar group;
Y₄ is either:
   —X₉, which is a further functional group able to react with a hydrolyzed functional group of the first organosilane molecule,
   —H, which is a hydrogen atom, or
   —R₆, which is an organic apolar group,
B₂, the presence of which is optional, is a bridging group,
Z₃ is either:
   —R₇, which is an organic apolar group,
   —H, which is a hydrogen atom, or
   -L₁, which is a ligand having an electron donor functionality and which is able to act as a metal nucleation site,
Z₄ is either:
   —R₈, which is an organic apolar group,
   —H, which is a hydrogen atom, or
   -L₂, which is a ligand having an electron donor functionality and which is able to act as a metal nucleation site, and
L is a ligand having an electron donor functionality and is able to act as a metal nucleation site,

Some examples of second organosilanes according to the description include:

### Example 1

### Strong Amino (Basic) Group for Coupling, and a Vinyl Ligand for Nucleation

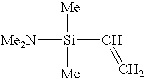

### Example 2

### Alternative Acidic Fluoromethenesulfonate Coupling Group

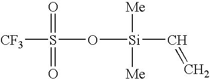

### Example 3

### Alternative Acetylenyl Ligand

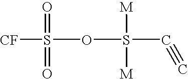

In general, the various non-limitative examples of the bridging groups B, the functional groups X, the organic groups R, and the ligands L as described above with respect to the passivating coupling composition are equally applicable to the silane components that constitute the composition.

In addition, the one or more ligands presented have an electron donor functionality and provide nucleation sites for the subsequently deposited metal. The fact that Z₃ and/or Z₄ can additionally be corresponding ligands further enhances the formation of a metal layer by presenting additional nucleation sites.

The ligands provided in the passivating coupling material according to the present invention are meant to provide metal nucleation sites in order to promote or facilitate metal layer formation. However, in certain situations, the ligands may react with other metallic structures in a semiconductor device (such as copper metal exposed in etched vias, or metallic barrier layers in the semiconductor device, like a cobalt or nickel alloy-based self-aligned barrier layer).

A problem could arise if, for example, the ligands reacted with, for example, a copper metal structure in an exposed via. One possible result is that the functional groups could react with surface hydroxyls on the dielectric (as intended), but this would cause, in essence, the both “ends” of the polymer to be attached to the dielectric layer. Another undesirable possibility is that the functional groups X might simply remain unattached, such that the polymer is, in a sense, inverted from its intended orientation. In either case, the passivating coupling material would present a reduced ability to promote metal layer deposition because of the reduction in available ligands acting as nucleation sites.

Accordingly, it may be desirable to formulate the passivating coupling material to reduce or avoid such interaction with other metallic structures forming part of the semiconductor device. Alternatively, some additional processing steps could be implemented in order to render the metal structures relatively insensitive to the passivating coupling material.

With respect to the latter possibility, the surface of, for example, a copper metal structure could be treated (i.e., protectively covered with) with a chemically appropriate organic amine. This modification of the copper metal surface can give rise to chemical bonds with the passivating coupling material which are relatively weaker than those between the passivating coupling material and the dielectric material. After the passivating coupling material has been thereafter deposited, a subsequent degassing step (using, for example, a thermal treatment) can be applied to remove any passivating coupling material from the copper metal areas. This removal is facilitated by the above-mentioned weak bonds created by the pretreatment of the copper metal surface.

A pretreatment of metal surfaces as described hereinabove can be performed in yet another substrate processing station in the contemplated integrated system.

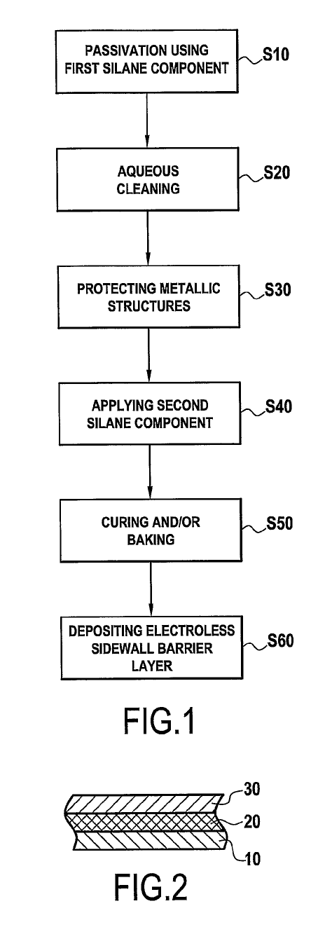

In view of the foregoing, an example of a process sequence according to the present invention includes (see FIG. 1):

passivating the dielectric layer with a first silane component (for example, by controlled atmosphere spraying or by vapor phase deposition) (step S10);

aqueous cleaning of vias, so as to simultaneously hydrolyze one or more functional groups of the deposited first silane component (such as the first polymeric components described above) (using, for example, liquid phase application, controlled atmosphere spray, or vapor phase deposition) (step S20);

optionally protecting a metallic layer (such as a copper cap layer) in the device structure to prevent or at least weaken bonding between the passivating coupling material and the metallic layer, as described above (in a controlled atmosphere, or in vapor phase) (step S30);

applying a second silane component (such as described above) (for example, in liquid phase, spray (optionally using an organic solvent), or in vapor phase; may optionally include drying assist) (step S40);

curing (for example, thermal) and/or baking in a controlled atmosphere (step 50); and

depositing an electroless sidewall barrier layer in liquid phase (for example, using immersion or spray) (step S60).

Once the porous dielectric material is appropriately passivated with the passivating coupling material of the present invention (whether in a single step or in multiple steps), metallization can be performed thereafter in liquid phase starting with an electroless deposition (as known, for example, from Shacham-Diamand, Electroch. Acta, vol. 44 (1999), 3639).

Thus, FIG. 2 very generally illustrates a dielectric layer 10 having a passivating coupling material layer 20 formed thereon. The passivating coupling material layer 20 acts, in view of the foregoing, to couple the dielectric layer 10 to a metal barrier layer 30 formed on the passivating coupling material layer.

After electroless deposition of a metallic barrier/seed layer, a copper film can be deposited thereon by conventional electroless deposition or electrodeposition, as are known in the field of semiconductor manufacture. Liquid application of the barrier metal layer on the passivating coupling layer permits metal deposition on the passivating coupling layer without having to “switch” process lines to gas phase metal deposition equipment.

The liquid phase barrier metal deposition can be performed in accordance with the foregoing description, for example, by seeding the nucleation sites presented by the passivating coupling material as described and claimed herein using liquid metal precursors or liquid metal salts, in a manner well known in the field of metal deposition. The composition of the alloy needs to be tailored to obtain satisfactory barrier properties in the sidewall barrier.

The optional above-described presence of multiple Si atoms in the backbone, plus the optional presence of a bridging group B, desirably increases the thermal stability of the passivating coupling material such that it can tolerate the temperatures associated with subsequent high-temperature manufacturing steps, such as gas phase deposition of a subsequent metal layer. In contrast, thermal decomposition of the shielding groups, if any, can be acceptable because their steric shielding function is no longer needed at that point in the fabrication process.

In an alternative process, aqueous via cleaning following passivation, as mentioned above, could be replaced by an initial step of via cleaning using supercritical CO₂. This would be followed by a step of depositing a first organosilane component as described above, then a step of hydrating the structure to obtain distal hydroxyl sites on the first organosilane molecules (that is, to hydrolyze at least some of the terminal functional groups of the first organosilane). The thusly modified first organosilane can then be reacted with one of the second organosilanes described above. Electroless barrier layer deposition and electrodeposition of copper would then follow as already described.

In yet another alternative process, a conventional aqueous via cleaning is first performed. Then, a first organosilane component as described above is applied using suitable methods (such as liquid phase deposition, spray, or vapor phase deposition). The structure is then hydrated in an aqueous media to hydrolyze the ends of the first organosilanes formed on the dielectric layer structure. A second organosilane is then deposited as described above, so that a respective one of its functional groups can react with a corresponding hydrolyzed functional group of the first organosilane, followed by electroless barrier layer deposition and electroless or electrodeposition of copper.

Although not described in particular detail here, one or more additional processing stations can be provided according to the nature of the semiconductor device being fabricated, including, without limitation, stations for electroplating (including electroplating a copper film on the barrier layer), polishing (for example, chemical mechanical polishing or electro-polishing), or seed layer deposition. As mentioned above, a separate semiconductor substrate cleaning station could be provided or that functionality could be combined with that of coupling layer deposition station.

Although the present invention has been described above with reference to certain particular preferred embodiments, it is to be understood that the invention is not limited by reference to the specific details of those preferred embodiments. More specifically, the person skilled in the art will readily appreciate that modifications and developments can be made in the preferred embodiments without departing from the scope of the invention as defined in the accompanying claims.

1. An integrated semiconductor substrate processing system, comprising:
a plurality of semiconductor substrate processing stations; and
a semiconductor substrate transport system for transferring a semiconductor substrate between the plurality of semiconductor substrate processing stations, wherein one of the semiconductor substrate processing stations is a barrier layer deposition station constructed and arranged to deposit a metal barrier layer in liquid phase on the semiconductor substrate, and in that the plurality of semiconductor substrate processing stations are integrated in a single physical unit.

2. A system according to claim 1, wherein the plurality of semiconductor processing stations comprises a coupling layer deposition station constructed and arranged to deposit a coupling layer on the semiconductor substrate prior to depositing the barrier layer thereon, the coupling layer having a chemical composition promoting the formation of the barrier layer thereon.

3. A system according to claim 2, wherein the coupling layer deposition station is constructed and arranged to deposit an organosilane coupling layer having the general formula: 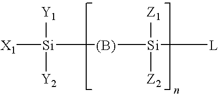
in which:
n is an integer equal to or greater than 1,
each Si is a silicon atom;
X₁ is a functional group able to react with a surface hydroxyl site of the dielectric material,
Y₁ is either:
—X₂, which is a further functional group able to react with a surface hydroxyl site of the dielectric material,
—H, which is a hydrogen atom, or
—R₁, which is an organic apolar group;
Y₂ is either:
—X₃, which is a further functional group able to react with a surface hydroxyl site of the dielectric material,
—H, which is a hydrogen atom, or
—R₂, which is an organic apolar group,
B, the presence of which is optional, is a bridging group,
Z₁ is either:
—R₃, which is an organic apolar group,
—H, which is a hydrogen atom, or
-L₁, which is a ligand having an electron donor functionality and is able to act as a metal nucleation site for promoting the formation of the barrier layer,
Z₂ is either:
—R₄, which is an organic apolar group,
—H, which is a hydrogen atom, or
-L₂, which is a ligand having an electron donor functionality and which is able to act as a metal nucleation site for promoting the formation of the barrier layer, and
L is a ligand able to act as a metal nucleation site for promoting the formation of the barrier layer.

4. A system according to claim 3, wherein at least one of Z₁ and Z₂ is, respectively, R₃ and R₄.

5. (canceled)

6. A system according to claim 3, wherein:
X₁, and X₂ and/or X₃ if present, are selected from the group consisting of: -chloride, -bromide, iodine, acryloxy-, alkoxy-, acetamido, acetyl-, allyl-, amino-, cyano-, epoxy-, imidazolyl, mercapto-, methanosulfonato-, sulfonato-, triflouroacetamido, and urea-containing groups, and
L, and L₁ and/or L₂ if present, is selected from the group consisting of vinyl, allyl, 2-butynyl, cyano, cyclooctadienyl, cyclopentadienyl, phosphinyl, alkylphosphinyl, sulfonato, and amine groups.

7. A system according to claim 1, wherein B, if present, is a silylene or a carbene group.

8. A system according to claim 7, wherein B is selected from the group consisting of m-phenylene, p-phenylene, and p,p′-diphenyl ether.

9. A system according to claim 1, wherein R₁, R₂, R₃, and/or R₄, if present, are selected from the group consisting of methyl, ethyl, propyl, butyl, phenyl, pentafluorophenyl, 1,1,2-trimethylpropyl(thexyl), and allyl.

10. A system according to claim 2, wherein it further comprises a dielectric layer deposition station constructed and arranged to deposit a dielectric layer on the semiconductor substrate, wherein the coupling layer deposition station is constructed and arranged to deposit the coupling layer on the deposited dielectric layer.

11. (canceled)

12. A system according to claim 3, wherein the coupling layer deposition station comprises means for dispersing a liquid solution containing the organosilane constituting the coupling layer onto a surface of the semiconductor substrate.

13. A system according to claim 1, further comprising a semiconductor substrate cleaning station constructed and arranged to clean a surface of a semiconductor substrate.

14. A system according to claim 13, wherein the semiconductor substrate cleaning station is constructed and arranged to clean a surface of a semiconductor substrate before the coupling layer deposition station deposits the coupling layer.

15. A system according to claim 13, wherein a single semiconductor processing station functions as both the coupling layer deposition station and the semiconductor substrate cleaning station, wherein the single semiconductor processing station functioning as both the coupling layer deposition station and the semiconductor substrate cleaning station is constructed and arranged to apply an aqueous solution on the semiconductor substrate, the aqueous solution containing in combination at least one cleaning composition for cleaning a surface of the semiconductor substrate and the organosilane constituting the coupling layer onto a surface of the semiconductor substrate.

16. A system according to claim 2, wherein the coupling layer deposition station is constructed and arranged to deposit a material constituting the coupling layer in a gas phase.

17. A system according to claim 16, wherein the material constituting the coupling layer is combined with a carrier gas.

18. A system according to claim 1, wherein the barrier layer deposition station is constructed and arranged to deposit a liquid phase metallic barrier layer at a temperature of less than about 80° C.

19. A system according to claim 1, wherein in it further comprises one or more of:
an electroplating station constructed and arranged to deposit an electroplated layer;
a polishing station constructed and arranged to polish a surface on the semiconductor substrate; and
a seed layer deposition station constructed and arranged to deposit a seed layer.

20. A system according to claim 19, wherein the seed layer deposition station is constructed and arranged to deposit a seed layer in liquid phase.

21. A system according to claim 2, wherein the coupling layer deposition station is constructed and arranged to deposit a first organosilane on the semiconductor substrate, the first organosilane having the general formula: 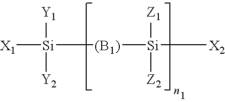
in which:
n₁ is an integer greater than or equal to 1,
each Si is a silicon atom;
X₁ is a functional group able to react with a surface hydroxyl site of the dielectric material,
Y₁ is either:
—X₃, which is a further functional group able to react with a surface hydroxyl site of the dielectric material,
—H, which is a hydrogen atom, or
—R₁, which is an organic apolar group;
Y₂ is either:
—X₄, which is a further functional group able to react with a surface hydroxyl site of the dielectric material,
—H, which is a hydrogen atom, or
—R₂, which is an organic apolar group,
B₁, the presence of which is optional, is a bridging group,
Z₁ is either:
—R₃, which is an organic apolar group,
—H, which is a hydrogen atom, or
—X₅, which is a hydrolizable functional group,
Z₂ is either:
—R₄, which is an organic apolar group,
—H, which is a hydrogen atom, or
—X₆, which is a hydrolizable functional group; and
X₂ is a hydrolizable functional group; and
a second organosilane having a functional group able to react with a hydrolyzed functional group of the first organosilane, and a ligand for providing a metal nucleation site,

22. A system according to claim 21, wherein the coupling layer deposition station is further constructed and arranged to deposit a second organosilane on the first organosilane, the second organosilane having a functional group able to react with a hydrolyzed functional group of the first organosilane and a ligand for providing a metal nucleation site, the second organosilane having the general formula: 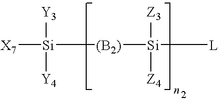
in which:
n₂ is an integer equal to or greater than or equal to 0,
each Si is a silicon atom;
X₇ is a functional group able to react with a hydrolyzed functional group of the first organosilane molecule,
Y₃ is either:
—X₈, which is a further functional group able to react with a hydrolyzed functional group of the first organosilane molecule,
—H, which is a hydrogen atom, or
—R₅, which is an organic apolar group;
Y₄ is either:
—X₉, which is a further functional group able to react with a hydrolyzed functional group of the first organosilane molecule,
—H, which is a hydrogen atom, or
—R₆, which is an organic apolar group,
B₂, the presence of which is optional, is a bridging group,
Z₃ is either:
—R₇, which is an organic apolar group,
—H, which is a hydrogen atom, or
-L₁, which is a ligand having an electron donor functionality and which is able to act as a metal nucleation site,
Z₄ is either:
—R₈, which is an organic apolar group,
—H, which is a hydrogen atom, or
-L₂, which is a ligand having an electron donor functionality and which is able to act as a metal nucleation site, and
L is a ligand having an electron donor functionality and is able to act as a metal nucleation site.
